(19) United States
(12) Patent Application Publication
(10) Pub. No.: US 2025/0088157 A1
(43) Pub. Date: Mar. 13, 2025

(54) SEMICONDUCTOR DEVICE

(71) Applicant: Hitachi, Ltd., Tokyo (JP)

(72) Inventors: Masahiro MASUNAGA, Tokyo (JP); Shinji NOMOTO, Tokyo (JP); Ryo KUWANA, Tokyo (JP); Isao HARA, Tokyo (JP)

(21) Appl. No.: 18/586,906

(22) Filed: Feb. 26, 2024

(30) Foreign Application Priority Data
Sep. 11, 2023 (JP) 2023-146718

(51) Int. Cl. H03F 3/45

(52) U.S. Cl. CPC H03F 3/45744; H03F 3/45278

(57) ABSTRACT

Provided is a semiconductor device including: an amplifier configured by an element made of silicon carbide, and including a differential amplifier circuit that amplifies an input signal; and a power supply circuit that supplies a voltage to the amplifier. Here, the voltage fluctuation amount reduction circuit is inserted between the power supply circuit and the amplifier. As a result, it possible to appropriately eliminate an influence of drift when the amplifier is configured by a semiconductor made of silicon carbide.

### CROSS-REFERENCE TO RELATED APPLICATION

The present application claims priority from Japanese application JP2023-146718, filed on Sep. 11, 2023, the content of which is hereby incorporated by reference into this application.

### BACKGROUND OF THE INVENTION

### 1. Field of the Invention

The present invention relates to a semiconductor device.

### 2. Description of the Related Art

In recent years, semiconductors configured by elements made of silicon carbide (SiC) are becoming widespread. A device made of silicon carbide has different characteristics from a conventional device made of silicon, and has various advantages. For example, a semiconductor made of silicon carbide is excellent in radiation resistance performance, and thus is suitable for a measurement system of a nuclear power device and a device used in space such as an artificial satellite.

For example, it is considered to configure an amplifier called a differential amplifier circuit by an element made of silicon carbide.

JP 2023-31429 A describes that a circuit having excellent radiation resistance is configured using a semiconductor made of silicon carbide. It is described that, in the case in which a semiconductor device is made of silicon carbide, the technique described in JP 2023-31429 A has a problem that a spike voltage is generated during startup, and a circuit configuration having an excellent spike resistance is provided to deal with this problem.

### SUMMARY OF THE INVENTION

Meanwhile, when a measurement system having excellent radiation resistance is configured using a semiconductor made of silicon carbide, an amplifier (differential amplifier circuit) is configured using a semiconductor made of silicon carbide.

However, when the amplifier is made of a semiconductor made of silicon carbide, there is a problem that a voltage during startup affects an input terminal of the amplifier and drifts an offset voltage. Since an influence of this drift is present over several hours, in the case of a measurement system that measures an output signal of an amplifier, for example, accurate measurement cannot be performed.

In addition, the problem that the semiconductor made of silicon carbide drifts the offset voltage is considered to be caused by the characteristics of the material itself that constitutes the semiconductor, as well as by the fact that the manufacturing process becomes more unstable in the case of the semiconductor made of silicon carbide than in the case of a semiconductor made of silicon.

In view of the above, an object of the present invention is to provide a semiconductor device capable of obtaining an output signal without an influence of drift even when an amplifier is configured by a semiconductor made of silicon carbide.

In order to solve the above problem, the configuration described in the claims is adopted, for example.

The present application provides a plurality of means for solving the above problem, one example of which is a semiconductor device including: an amplifier configured by an element made of silicon carbide, and including a differential amplifier circuit that amplifies an input signal; and a power supply circuit that supplies a voltage to the amplifier, where a voltage fluctuation amount reduction circuit is inserted between the power supply circuit and the amplifier.

According to the present invention, it is possible to prevent a drift of an offset voltage from occurring by a voltage fluctuation amount reduction circuit, and to suppress a fluctuation of an output signal due to the drift of the offset voltage in the case where a differential amplifier circuit is configured by an element made of silicon carbide.

Problems, configurations, and effects other than those described above will become apparent from the following description of embodiments.

### BRIEF DESCRIPTION OF THE DRAWINGS

FIG. 1 is a circuit diagram of a semiconductor device according to a first embodiment of the present invention;

FIG. 2 is an overall configuration diagram of the semiconductor device according to the first embodiment of the present invention;

FIG. 3 is a circuit diagram of a dV/dt reduction circuit of the semiconductor device according to the first embodiment of the present invention;

FIG. 4 is a characteristic diagram of a dV/dt reduction circuit of the semiconductor device according to the first embodiment of the present invention;

FIG. 5 is a circuit diagram of a semiconductor device according to a second embodiment of the present invention;

FIG. 6 is a characteristic diagram of a semiconductor device according to the second embodiment of the present invention;

FIG. 7 is a circuit diagram showing an example of a conventional semiconductor device;

FIG. 8 is a characteristic diagram showing an operation example of the conventional semiconductor device;

FIG. 9 is a characteristic diagram comparing a characteristic according to the present invention with a conventional offset voltage; and

FIG. 10 is a circuit diagram showing a modified example of the semiconductor device according to the embodiments of the present invention.

### DESCRIPTION OF THE PREFERRED EMBODIMENTS

### First Embodiment

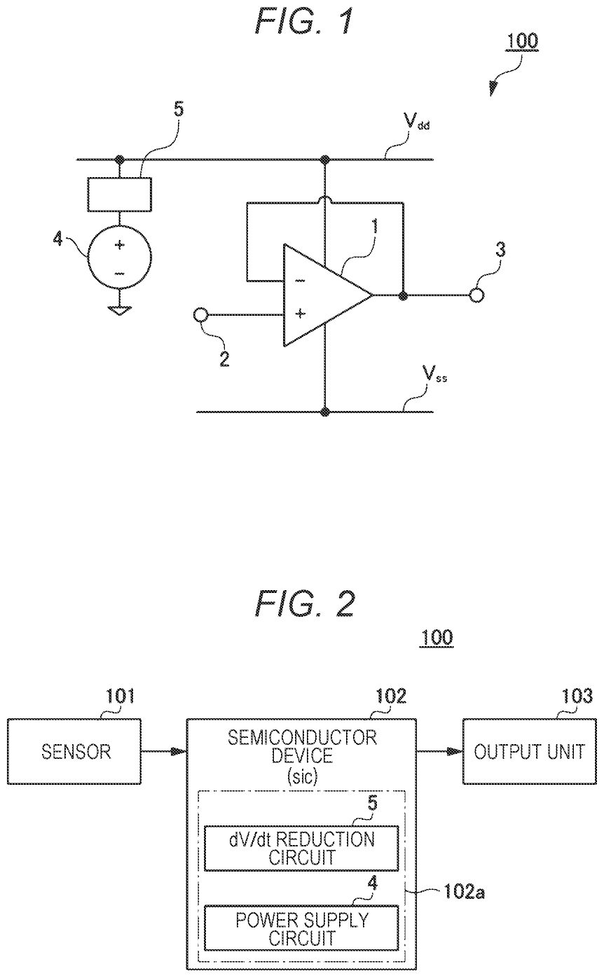

Hereinafter, a semiconductor device according to a first embodiment of the present invention will be described with reference to FIGS. 1 to 4.

FIG. 1 shows a circuit of a semiconductor device according to this embodiment.

The semiconductor device of this embodiment is a semiconductor device used as a measurement system 100, and includes an amplifier 1 having a differential amplifier circuit that amplifies an input signal.

The amplifier 1 is configured by a semiconductor made of silicon carbide (SiC). Hereinafter, the amplifier 1 is referred to as a SiC amplifier.

The SiC amplifier 1 has a positive input terminal (non-inverting input terminal) and a negative input terminal (inverting input terminal), and a signal obtained by a measurement signal input terminal 2 is supplied to the positive input terminal. Then, at an output terminal 3, the SiC amplifier 1 obtains a signal obtained by amplifying a difference between the signals obtained at the positive input terminal and the negative input terminal. The negative input terminal and the output terminal 3 are connected, and an output from the SiC amplifier 1 is fed back to the negative input terminal.

The SiC amplifier 1 has a positive power supply terminal and a negative power supply terminal. A positive power supply V_{dd} is supplied to the positive power supply terminal of the SiC amplifier 1, and a negative power supply Vₛₛ is supplied to the negative power supply terminal of the SiC amplifier 1.

The positive power supply V_{dd} is supplied from a power supply circuit 4. The negative power supply Vₛₛ is, for example, a ground potential of the power supply circuit 4.

In this embodiment, a dV/dt reduction circuit 5 is connected between the power supply circuit 4 and the positive power supply V_{dd}. The dV/dt reduction circuit 5 functions as a voltage fluctuation amount reduction circuit, and reduces a voltage fluctuation amount dV in a unit time dt. Here, a change amount dV per unit time dt is a change amount at least lower than 15 V/ms.

In the case of the configuration of FIG. 1, the dV/dt reduction circuit 5 is connected between a positive side of power supply circuit 4 and a line of the positive power supply V_{dd}.

FIG. 2 shows a configuration example of the entire measurement system 100 including the SiC amplifier 1 having the circuit configuration illustrated in FIG. 1.

The measurement system 100 includes a sensor 101, a semiconductor device 102, and an output unit 103.

The sensor 101 measures various states such as a pressure and a water level, and outputs a measurement signal. For example, the sensor 101 measures the water level in a pressure vessel of a nuclear power plant. A voltage value of the measurement signal by the sensor 101 varies.

The measurement signal output from the sensor 101 is supplied to the semiconductor device 102. The semiconductor device 102 has the same configuration as that illustrated in FIG. 1, for example, and includes the SiC amplifier 1 (FIG. 1).

A power supply unit 102a of the semiconductor device 102 includes the power supply circuit 4 and the dV/dt reduction circuit 5.

Then, the measurement signal amplified by the semiconductor device 102 is supplied to the output unit 103, and outputs a voltage signal which is the measurement signal. The output processing of the measurement signal in the output unit 103 includes display and recording of a voltage value, transmission to the outside, and the like.

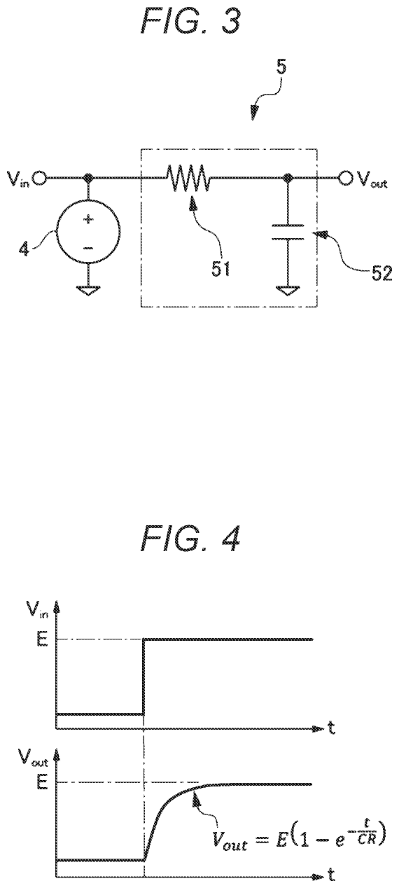

FIG. 3 shows a configuration example of the dV/dt reduction circuit 5.

The example illustrated in FIG. 3 is an example of the dV/dt reduction circuit 5 connected between the power input Vᵢₙ and the power output Vₒᵤₜ. The power supply circuit 4 is connected to the power input Vᵢₙ.

In dV/dt reduction circuit 5, a resistor 51 is connected in series between the power input Vᵢₙ and the power output Vₒᵤₜ, and one end of a capacitor 52 is connected between the resistor 51 and the power output Vₒᵤₜ. The other end of the capacitor 52 is connected to a ground potential portion.

The resistor 51 and the capacitor 52 of the configuration shown in FIG. 3 function as a low-pass filter, and the voltage fluctuation amount dV in the unit time dt is reduced by a passive circuit having the resistor 51 and the capacitor 52.

FIG. 4 shows characteristics of the dV/dt reduction circuit 5 illustrated in FIG. 3.

The upper characteristic diagram in FIG. 4 shows a time variation (horizontal axis) of the voltage (vertical axis) of the power input Vᵢₙ.

The lower characteristic diagram in FIG. 4 shows a time variation (horizontal axis) of the voltage (vertical axis) of the power output Vₒᵤₜ obtained through the dV/dt reduction circuit 5.

As illustrated in the upper characteristic diagram in FIG. 4, the power supply circuit 4 is started up at a certain timing to output a voltage E.

At this time, as illustrated in the lower characteristic diagram in FIG. 4, the power output Vₒᵤₜ rises up to the voltage E with a certain time constant by an action of the low-pass filter including the resistor 51 and the capacitor 52.

When the characteristics of the resistor 51 and the capacitor 52 are denoted respectively by R and C, the power output Vₒᵤₜ has characteristics expressed by the following [Expression 1].

Vₒᵤₜ=E(1−et/CR) [1]

According to the measurement system 100 configured as described above, it is possible to prevent the drift of the offset voltage, and it is possible to suppress the fluctuation of the output signal due to the drift of the offset voltage when the SiC amplifier 1 including the element made of silicon carbide is used.

### Second Embodiment

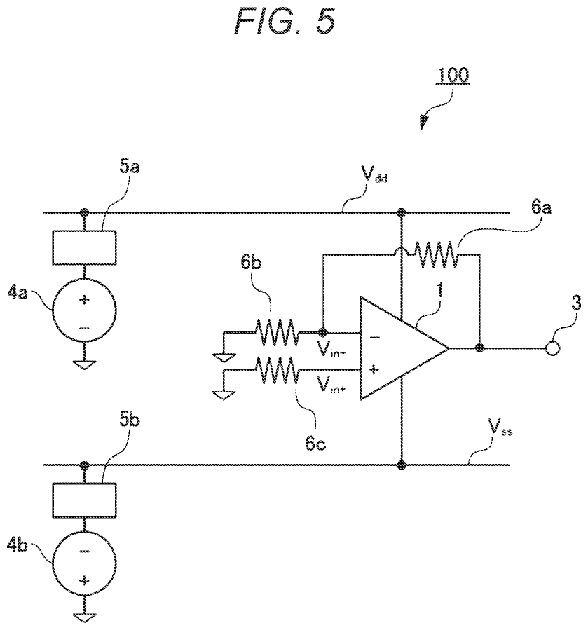

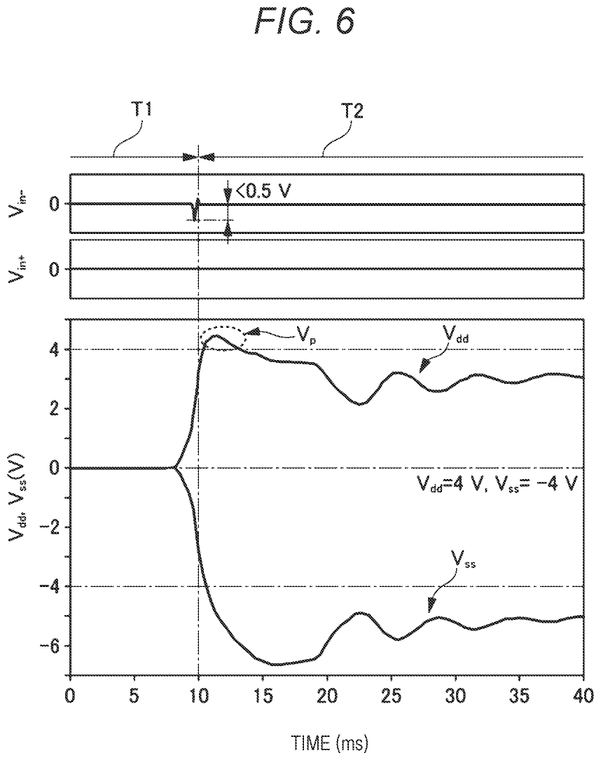

Next, a semiconductor device according to a second embodiment of the present invention will be described with reference to FIGS. 5 to 6. In FIGS. 5 and 6, the same portions as those in FIGS. 1 to 4 described in the first embodiment are denoted by the same reference numerals, and redundant description will be omitted.

FIG. 5 shows a circuit of a semiconductor device according to this embodiment.

In the SiC amplifier 1 made of a semiconductor made of silicon carbide (SiC), a resistor 6a is connected between the output terminal 3 and the negative input terminal Vᵢₙ₋.

Further, a resistor 6c is connected to the positive input terminal Vᵢₙ₊ of the SiC amplifier 1, and an input signal to the SiC amplifier 1 is supplied via the resistor 6c.

In addition, a resistor 6b is connected to the negative input terminal Vᵢₙ₋ of the SiC amplifier 1.

Then, the positive power supply V_{dd} is supplied from a power supply circuit 4a to the positive power supply terminal of the SiC amplifier 1, and the negative power supply Vₛₛ is supplied from a power supply circuit 4b to the negative power supply terminal of the SiC amplifier 1.

Here, the dV/dt reduction circuit 5a is connected between the power supply circuit 4a and the positive power supply terminal of the SiC amplifier 1. Similarly, a dV/dt reduction circuit 5b is connected between the power supply circuit 4b and the negative power supply terminal of the SiC amplifier 1.

Each of the dV/dt reduction circuits 5a and 5b includes a filter including passive components (a resistor and a capacitor) illustrated in FIG. 3, for example.

FIG. 6 shows a characteristic example of the circuit illustrated in FIG. 5.

In the example of FIG. 6, the vertical axis represents the negative input terminal Vᵢₙ₋, the positive input terminal Vᵢₙ₊, the positive power supply V_{dd}, and the negative power supply Vₛₛ of the SiC amplifier 1, and the horizontal axis represents the time variation (ms).

As illustrated in FIG. 6, at the timing when a startup period T1 ends, the positive power supply V_{dd} and the negative power supply Vₛₛ rise up to prescribed voltages. Here, it is assumed that the positive power supply V_{dd}=4 V and the negative power supply Vₛₛ=−4 V.

A period T2 in which a virtual short circuit is functioning follows the termination of the startup period T1.

In the example of FIG. 6, an overshoot of the input voltage of the negative input terminal Vᵢₙ₋ occurs immediately before the startup period T1 ends. This overshoot is equal to or less than 0.5 V.

At this time, by an action of the dV/dt reduction circuits 5a and 5b, the timing at which an overshoot peak Vₚ occurs in the positive power supply V_{dd} is shifted into the period T2 in which the virtual short circuit is functioning. That is, the voltage output from the power supply circuits 4a and 4b during startup is in a state lower than the power supply voltage value that converges until a virtual short circuit occurs between the two input terminals Vᵢₙ₋ and Vᵢₙ₊.

As a result, it is possible to eliminate an adverse effect on the output signal when the SiC amplifier 1 including the element made of silicon carbide is used.

The positive power supply V_{dd} and the negative power supply Vₛₛ gradually converge to 4 V or −4 V in the period T2 in which the virtual short circuit is functioning.

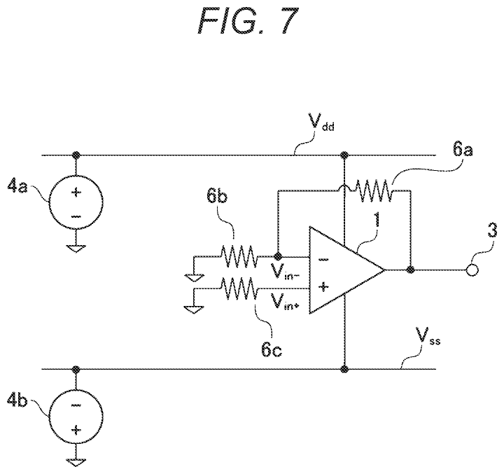

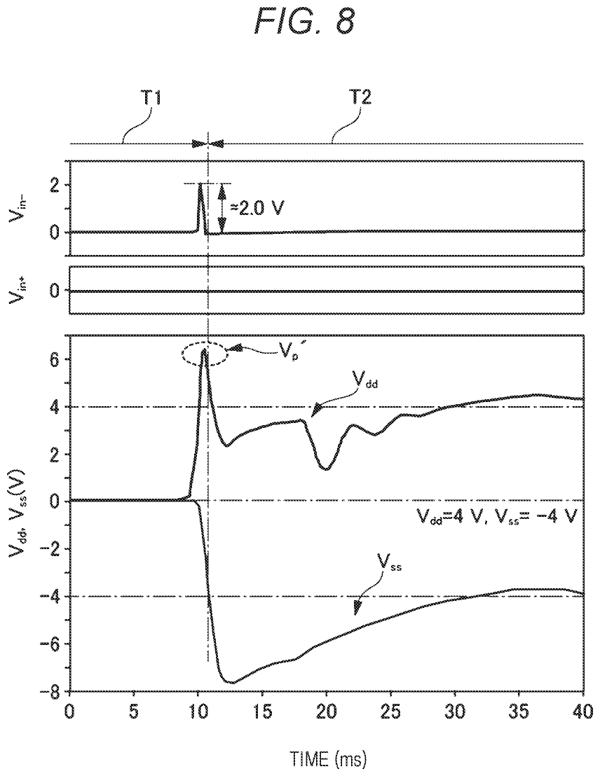

Here, a configuration in a case where the dV/dt reduction circuits 5a and 5b are not provided for the semiconductor device illustrated in FIG. 5 (conventional configuration: FIG. 7) and characteristics in the configuration of FIG. 7 will be described (FIG. 8) for reference.

In the case of the semiconductor device illustrated in FIG. 7, the positive power supply V_{dd} is supplied from the power supply circuit 4a to the positive power supply terminal of the SiC amplifier 1, and the negative power supply Vₛₛ is supplied from the power supply circuit 4b to the negative power supply terminal of the SiC amplifier 1. Here, the dV/dt reduction circuits 5a and 5b are not connected to the power supply circuits 4a and 4b, respectively.

Referring to FIG. 8 in which the characteristics in the case of the configuration illustrated in FIG. 7 are shown, an overshoot of the input voltage of the negative input terminal Vᵢₙ₋ occurs immediately before the startup period T1 ends. This overshoot is about 2.0 V.

At this time, an overshoot peak Vₚ′ occurs in the positive power supply V_{dd} at substantially the same timing as the overshoot of the input voltage of the negative input terminal Vᵢₙ₋.

In the case of the characteristics of the embodiment illustrated in FIG. 6, the timing at which the overshoot peak Vₚ occurs is shifted into the period T2 in which the virtual short circuit is functioning.

On the other hand, in the characteristics illustrated in FIG. 8, the timing at which the overshoot peak Vₚ′ occurs is the overshoot peak Vₚ′ in the startup period T1.

As can be seen from comparison with the characteristics of this embodiment illustrated in FIG. 6, in the case of the characteristics according to the conventional configuration illustrated in FIG. 8, there is an adverse effect due to the overshoot peak Vₚ′ in the startup period T1, whereas in the case of the characteristics of this embodiment, an adverse effect due to the overshoot peak Vₚ can be eliminated.

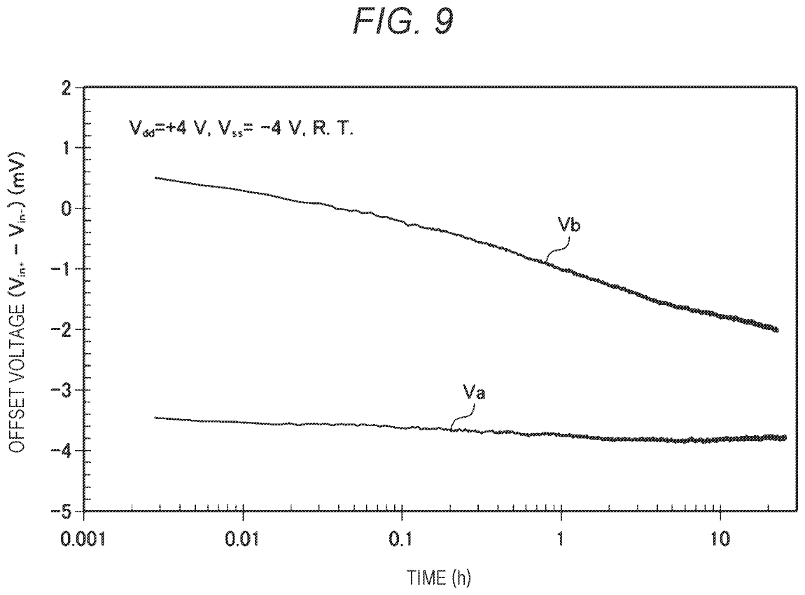

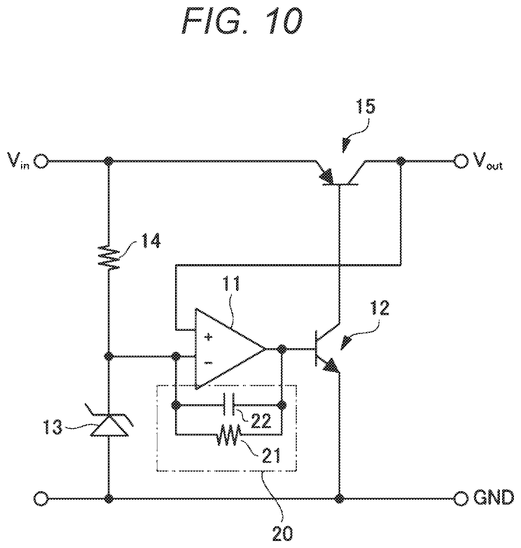

FIG. 9 is a comparison of the offset voltage (vertical axis) of the SiC amplifier 1 between the characteristic Va of the configuration of FIG. 5 (configuration having the dV/dt reduction circuits 5a and 5b) and the characteristic Vb of the configuration of FIG. 7 (configuration without the dV/dt reduction circuits 5a and 5b). The horizontal axis in FIG. 9 represents time (h). In the example of FIG. 9, the positive power supply V_{dd} is 4 V, and the negative power supply Vₛₛ is −4 V.

Here, the offset voltage of the SiC amplifier 1 is a value obtained by subtracting the voltage of the negative input terminal Vᵢₙ₋ from the voltage of the positive input terminal Vᵢₙ₊.

The characteristic Va of the configuration having the dV/dt reduction circuits 5a and 5b is generally stable in any time zone with an offset voltage of about −3.4 V to −3.6 V.

On the other hand, in the case of the characteristic Vb of the configuration without the dV/dt reduction circuits 5a and 5b, the offset voltage greatly fluctuates from around +0.5 V to around −2 V over a long period of time.

Therefore, by providing the dV/dt reduction circuits 5a and 5b, it is possible to satisfactorily suppress the fluctuation of the offset voltage during startup.

### <Modified Example>

It should be noted that the above-described embodiments have been described in detail in order to describe the present invention in an easy-to-understand manner, and it is not necessarily intended to limit to those having all of the described configurations.

For example, while the power supply circuit having a configuration independent of the SiC amplifier 1 is connected in the above-described embodiments, but a similar dV/dt reduction circuit may be connected to a configuration in which the SiC amplifier and the power supply circuit are integrated.

FIG. 10 shows a configuration example of this case.

In the example of FIG. 10, a series circuit of a Zener diode 13 and a resistor 14 is connected between the power input Vᵢₙ and a ground potential portion GND. Then, a connection point between the Zener diode 13 and the resistor 14 is connected to a negative input terminal of a SiC amplifier 11.

An output terminal of the SiC amplifier 11 is connected to a base of an NPN bipolar junction transistor 12. An emitter of the transistor 12 is connected to the ground potential portion GND, and a collector of the transistor 12 is connected to a base of a PNP bipolar junction transistor 15.

An emitter of the transistor 15 is connected to the power input Vᵢₙ, and a collector of the transistor 15 is connected to the power input Vₒᵤₜ.

Further, the power input Vₒᵤₜ is connected to a positive input terminal of the SiC amplifier 11.

Then, a dV/dt reduction circuit 20 is connected between the output terminal of the SiC amplifier 11 and the negative input terminal of the SiC amplifier 11. In the example of FIG. 10, the dV/dt reduction circuit 20 is configured as a low-pass filter in which a resistor 21 and a capacitor 22 are connected in parallel.

In a case where the power supply circuit including the Zener diode 13 and the like is integrated with the SiC amplifier 11 as described above, the same effects as those of the first embodiment and the second embodiment can be obtained when the dV/dt reduction circuit 20 is connected between the power supply circuit and the SiC amplifier 11.

In addition, a configuration in which a dV/dt reduction circuit is configured by a filter using a passive component is a mere example, and the dV/dt reduction circuit may be a circuit having another circuit configuration that functions as a voltage fluctuation amount reduction circuit that reduces the voltage fluctuation amount dV in the unit time dt.

What is claimed is:

1. A semiconductor device comprising:
an amplifier configured by an element made of silicon carbide, and including a differential amplifier circuit that amplifies an input signal;
a power supply circuit that supplies a voltage to the amplifier; and
a voltage fluctuation amount reduction circuit inserted between the power supply circuit and the amplifier.

2. The semiconductor device according to claim 1, wherein
one of two input terminals of the differential amplifier circuit included in the amplifier is electrically connected to an output terminal of the amplifier, and
the voltage fluctuation amount reduction circuit shifts an overshoot peak of a power supply voltage of the power supply circuit during startup to a time point at which a virtual short circuit of the differential amplifier circuit functions.

3. The semiconductor device according to claim 2,
wherein a voltage output from the power supply circuit during startup is lower than a power supply voltage value that converges until a virtual short circuit between the two input terminals occurs.

4. The semiconductor device according to claim 1, wherein
the power supply circuit includes a first power supply circuit that supplies power on a positive electrode side of the differential amplifier circuit and a second power supply circuit that supplies power on a negative electrode side of the differential amplifier circuit, and
the voltage fluctuation amount reduction circuit is inserted between the first power supply circuit and the amplifier, and as well as between the second power supply circuit and the amplifier.

5. The semiconductor device according to claim 1,
wherein the voltage fluctuation amount reduction circuit is connected between one of input terminals of the differential amplifier circuit and an output terminal.

6. The semiconductor device according to claim 1, wherein the voltage fluctuation amount reduction circuit includes a filter including a passive component.

7. The semiconductor device according to claim 1, wherein
an input signal to the amplifier is a measurement signal, and
a signal obtained at an output terminal of the amplifier is output as an amplified measurement signal.
